(19) United States
(12) Patent Application Publication
(10) Pub. No.: US 2024/0429192 A1
(43) Pub. Date: Dec. 26, 2024

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventors: CHAJEA JO, Suwon-si (KR); Jaejun Lee, Suwon-si (KR); Hyiyeong Jang, Suwon-si (KR)

(21) Appl. No.: 18/401,625

(22) Filed: Dec. 31, 2023

(30) Foreign Application Priority Data
Jun. 26, 2023 (KR) 10-2023-0082179

(51) Int. Cl. H01L 23/00; H01L 25/00; H01L 25/10; H01L 25/18; H10B 80/00

(52) U.S. Cl. CPC H01L 24/20; H01L 24/08; H01L 24/19; H01L 25/105; H01L 25/18; H01L 25/50; H10B 80/00; H01L 23/481; H01L 24/16; H01L 2224/08225; H01L 2224/16227; H01L 2224/19; H01L 2224/211; H01L 2224/214; H01L 2224/221; H01L 2225/1023; H01L 2225/1041; H01L 2924/1431; H01L 2924/1436; H01L 2924/1437; H01L 2924/1438; H01L 2924/1443

(57) ABSTRACT

A semiconductor package includes a lower semiconductor chip including a first circuit layer, an upper semiconductor chip disposed on the lower semiconductor chip and including a second circuit layer, and an interconnection layer disposed between the lower semiconductor chip and the upper semiconductor chip, the interconnection layer including a plurality of pads, including at least a first pad offset from the lower semiconductor chip or the upper semiconductor chip, and a wiring portion horizontally extended and connecting the first pad of the plurality of pads to a second pad of the plurality of pads disposed between the lower semiconductor chip and the upper semiconductor chip, wherein the wiring portion of the interconnection layer electrically connects the first circuit layer to the second circuit layer.

### CROSS-REFERENCE TO RELATED APPLICATIONS

This application claims priority under 35 U.S.C. § 119 to Korean Patent Application No. 10-2023-0082179, filed on Jun. 26, 2023, in the Korean Intellectual Property Office, the entire contents of which are hereby incorporated by reference.

### TECHNICAL FIELD

The present disclosure relates to a semiconductor package and a method of manufacturing the same, and more particularly to a semiconductor package including an interconnection layer connecting semiconductor chips offset from each other.

### DISCUSSION OF RELATED ART

Demand for portable electronic devices has led to the development of high performance, small size, and lightweight electronic components that make up these devices. Among these electronic components, there is an increasing demand for memory-type semiconductor devices with high-performance, high bandwidth, and/or high processing capacity.

A reduction in the size of a component and/or an increase in device performance may lead to various difficulties. In particular, for a semiconductor package used to process high frequency signals, a reduction in size may need to be balanced with electrical characteristics such as reliability.

In general, packaging technologies have been developed to reduce device size and ensure device characteristics. For example, a through-silicon via (TSV) process, a flip chip process, a wire bonding process, or the like may be used to stack a plurality of memory chips on a package substrate. However, these processes may be associated with high complexity and high cost.

### SUMMARY

An embodiment of the inventive concept provides a semiconductor package with a high integration density and a method of manufacturing the same.

An embodiment of the inventive concept provides a semiconductor package with improved electrical characteristics and a method of manufacturing the same.

According to an embodiment of the inventive concept, a semiconductor package may include a lower semiconductor chip comprising a first circuit layer, an upper semiconductor chip disposed on the lower semiconductor chip and comprising a second circuit layer, and an interconnection layer disposed between the lower semiconductor chip and the upper semiconductor chip, the interconnection layer comprising a plurality of pads, including at least a first pad offset from the lower semiconductor chip or the upper semiconductor chip, and a wiring portion horizontally extended and connecting the first pad of the plurality of pads to a second pad of the plurality of pads disposed between the lower semiconductor chip and the upper semiconductor chip, wherein the wiring portion of the interconnection layer electrically connects the first circuit layer to the second circuit layer.

According to an embodiment of the inventive concept, a semiconductor package may include a package substrate, a lower semiconductor chip disposed on the package substrate, an upper semiconductor chip disposed on the lower semiconductor chip and horizontally offset from a portion the lower semiconductor chip, and an interconnection layer disposed between the lower semiconductor chip and the upper semiconductor chip. The interconnection layer covers a bottom surface of the upper semiconductor chip in a first region offset from the lower semiconductor chip. The upper semiconductor chip may include a first circuit layer provided on the bottom surface of the upper semiconductor chip. A thickness of an interconnection pattern of the first circuit layer may be less than a thickness of an interconnection pattern of the interconnection layer.

According to an embodiment of the inventive concept, a semiconductor package may include a package substrate, a first semiconductor chip disposed on the package substrate, a first mold layer disposed on the package substrate to surround the first semiconductor chip, a first interconnection layer covering a top surface of the first semiconductor chip and a top surface of the first mold layer, a second semiconductor chip on the first interconnection layer, a second mold layer disposed on the first interconnection layer to surround the second semiconductor chip, and a plurality of outer terminals disposed on a bottom surface of the package substrate. The second semiconductor chip may be horizontally offset from the first semiconductor chip and may vertically overlap a side surface of the first semiconductor chip. The first semiconductor chip and the first mold layer may be spaced apart from the second semiconductor chip and the second mold layer by the first interconnection layer.

According to an embodiment of the inventive concept, a semiconductor package may include a package substrate, a first semiconductor chip disposed on the package substrate, the first semiconductor chip including a first circuit layer, which is disposed on a surface of the first semiconductor chip, and a plurality of first vias, which vertically penetrate the first semiconductor chip and are coupled to the first circuit layer, a first mold layer disposed on the package substrate to enclose the first semiconductor chip, a second semiconductor chip disposed on and offset from the first semiconductor chip, the second semiconductor chip including a second circuit layer, which is disposed on a bottom surface of the second semiconductor chip, and a plurality of second vias vertically penetrating the second semiconductor chip and are coupled to the second circuit layer, a first interconnection layer disposed between the second circuit layer and the first semiconductor chip and between the second circuit layer and the first mold layer, and a second mold layer disposed on the first mold layer to enclose the first interconnection layer and the second semiconductor chip. The first interconnection layer may expose a top surface of the first semiconductor chip in a region beside the second semiconductor chip. The second semiconductor chip may be connected to the first interconnection layer through a plurality of chip pads of the second circuit layer. At least one of the chip pads may be disposed on a side surface of the first semiconductor chip, when viewed in a plan view, and an interconnection pattern of the first interconnection layer may electrically connect the at least one of the chip pads to the first vias.

According to an embodiment of the inventive concept, a method of manufacturing a semiconductor package may include providing a package substrate, mounting a first semiconductor chip on the package substrate, forming a first mold layer on the package substrate enclosing the first semiconductor chip, providing a second semiconductor chip, forming an interconnection layer on at least one of a top surface of the first semiconductor chip and a bottom surface of the second semiconductor chip, mounting the second semiconductor chip on a portion of the first semiconductor chip and a portion of the first mold layer, the second semiconductor chip being electrically connected to the first semiconductor chip through the interconnection layer, and forming a second mold layer on the first mold layer to enclose the second semiconductor chip.

### BRIEF DESCRIPTION OF THE DRAWINGS

FIG. 1 is a sectional view illustrating a semiconductor package according to an embodiment of the inventive concept.

FIG. 2 is a plan view illustrating a semiconductor package according to an embodiment of the inventive concept.

FIG. 3 is an enlarged sectional view illustrating a portion ‘A’ of FIG. 1.

FIG. 4 is a sectional view illustrating a semiconductor package according to an embodiment of the inventive concept.

FIG. 5 is a plan view illustrating a semiconductor package according to an embodiment of the inventive concept.

FIG. 6 is a sectional view illustrating a semiconductor package according to an embodiment of the inventive concept.

FIG. 7 is an enlarged sectional view illustrating a portion ‘B’ of FIG. 6.

FIG. 8 is a sectional view illustrating a semiconductor package according to an embodiment of the inventive concept.

FIG. 9 is a plan view illustrating a semiconductor package according to an embodiment of the inventive concept.

FIG. 10, FIG. 11, FIG. 12, FIG. 13, and FIG. 14 are sectional views illustrating a semiconductor package according to an embodiment of the inventive concept.

FIG. 15, FIG. 16, FIG. 17, FIG. 18, FIG. 19, FIG. 20, FIG. 21, and FIG. 22 are sectional views illustrating a method of manufacturing a semiconductor package according to an embodiment of the inventive concept.

### DETAILED DESCRIPTION

Example embodiments of the inventive concepts will now be described more fully with reference to the accompanying drawings.

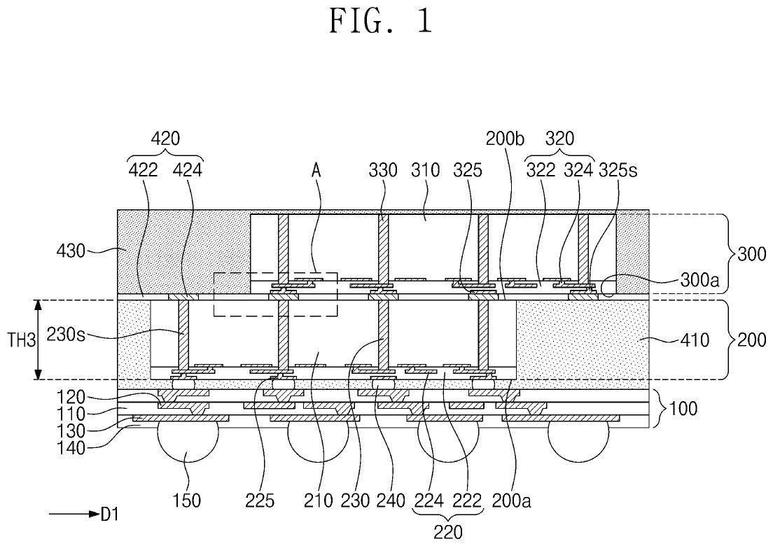

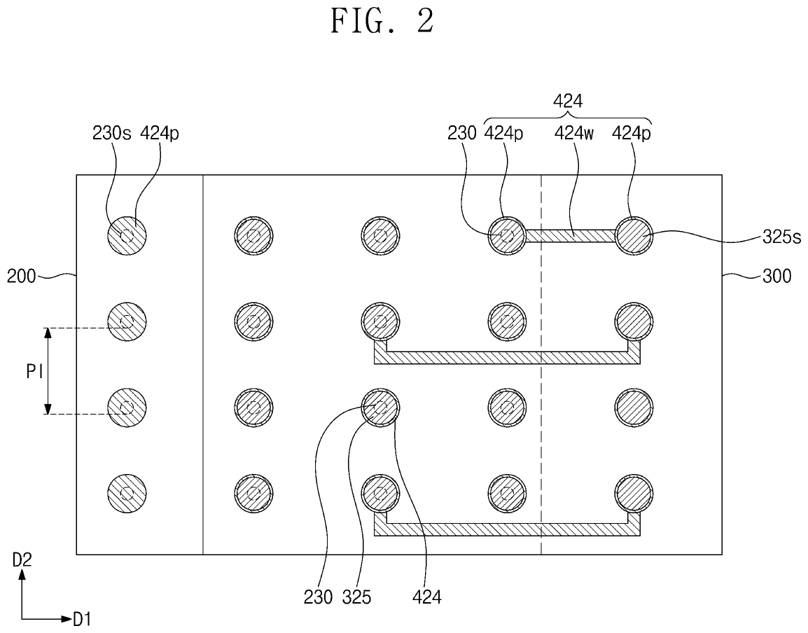

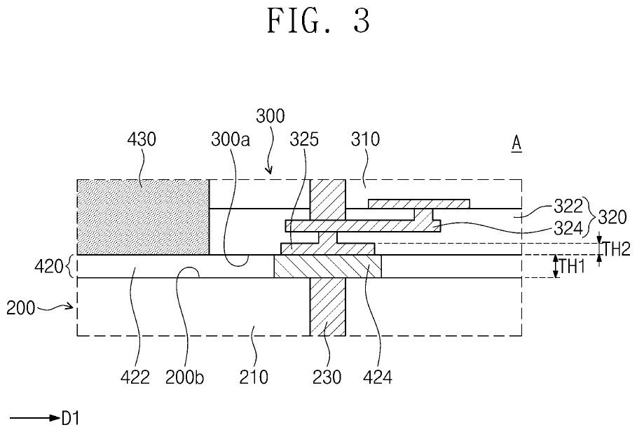

FIG. 1 is a sectional view illustrating a semiconductor package according to an embodiment of the inventive concept. FIG. 2 is a plan view illustrating a semiconductor package according to an embodiment of the inventive concept. FIG. 3 is an enlarged sectional view illustrating a portion ‘A’ of FIG. 1.

Referring to FIG. 1, a package substrate 100 may be provided. The package substrate 100 may be a redistribution substrate. For example, the package substrate 100 may include one or more substrate interconnection layers. In the case of two or more substrate interconnection layers, the substrate interconnection layers may be stacked. Each of the substrate interconnection layers may include a substrate insulating layer 110 and a substrate interconnection pattern 120 disposed in the substrate insulating layer 110. The substrate interconnection pattern 120 of a first substrate interconnection layer may be electrically connected to the substrate interconnection pattern 120 of a second substrate interconnection layer adjacent to the first substrate interconnection layer.

The substrate insulating layer 110 may include at least one of an insulating polymer or a photoimageable polymer (e.g., photoimageable dielectric (PID)). For example, the substrate insulating layer 110 may be formed of, or include at least one of, photo-imagable polyimides, polybenzoxazole (PBO), phenol-based polymers, or benzocyclobutene-based polymers.

The substrate interconnection pattern 120 may be disposed in the substrate insulating layer 110. The substrate interconnection pattern 120 may be horizontally extended in the substrate insulating layer 110. For example, the substrate interconnection pattern 120 may serve as a pad portion or a line portion of the substrate interconnection layer. In an embodiment, the substrate interconnection pattern 120 may be a structure for horizontal redistribution of signals or power within the package substrate 100. The substrate interconnection pattern 120 may be disposed in an upper portion of the substrate insulating layer 110. A top surface of the substrate interconnection pattern 120 may be exposed on a top surface of the substrate insulating layer 110. For example, the top surface of the substrate interconnection pattern 120 may be exposed to the outside of the substrate insulating layer 110 at the top surface of the substrate insulating layer 110. The substrate interconnection pattern 120 in an uppermost substrate interconnection layer may be used as a substrate pad. For example, the substrate interconnection pattern 120 in the uppermost substrate interconnection layer may be connected to a first semiconductor chip 200. The substrate interconnection pattern 120 may include a conductive material. For example, the substrate interconnection pattern 120 may be formed of, or include, a metallic material (e.g., copper (Cu)).

The substrate interconnection pattern 120 may include a via portion extended toward a bottom surface of the substrate insulating layer 110. The via portion may be a structure that is used to vertically connect adjacent ones of the substrate interconnection patterns 120. Alternatively, the via of the substrate interconnection pattern 120 portion may be a structure that is used to connect a lowermost one the substrate interconnection patterns to an outer pad 130. For example, the via portion may be extended from the bottom surface of the substrate interconnection pattern 120 to penetrate the substrate insulating layer 110 and may be coupled to a top surface of the substrate interconnection pattern 120 of a lower substrate interconnection layer. Alternatively, the via portion may be extended from the bottom surface of the substrate interconnection pattern 120 to penetrate the lowermost one of the substrate insulating layers and may be coupled to a top surface of the outer pad 130.

In an embodiment, in one of the substrate interconnection layers, the substrate interconnection pattern 120 may be disposed on the top surface of the substrate insulating layer 110, and the via portion of the substrate interconnection pattern 120 may penetrate the substrate insulating layer 110 and may be coupled to the substrate interconnection pattern 120 of a lower substrate interconnection layer.

The outer pads 130 may be provided on a bottom surface of the lowermost one of the substrate interconnection layers. The outer pads 130 may be electrically connected to the substrate interconnection pattern 120. Outer terminals 150 may be provided on, and coupled to, the outer pads 130. The outer pads 130 may electrically connect the substrate interconnection pattern 120 to the outer terminals 150.

A substrate protection layer 140 may be provided. The substrate protection layer 140 may be cover a bottom surface of the lowermost one of the substrate interconnection layers and expose the outer pads 130. The outer terminals 150 may be disposed on the exposed bottom surfaces of the outer pads 130. The outer terminals 150 may include, for example, solder balls or solder bumps.

The package substrate 100 may have the afore-described structure. However, the inventive concept is not limited to these examples. The package substrate 100 may be a printed circuit board (PCB). For example, the package substrate 100 may include a core layer and peripheral portions, which may be used to connect interconnections lines on and below the core layer.

The first semiconductor chip 200 may be disposed on the package substrate 100. The first semiconductor chip 200 may be a logic chip. In an embodiment, the first semiconductor chip 200 may be a memory chip (e.g., Dynamic Random Access Memory (DRAM), Static Random Access Memory (SRAM), Magnetoresistive Random Access Memory (MRAM), or FLASH memory chip). The first semiconductor chip 200 may have a front surface 200a and a rear surface 200b. Hereinafter, in the present specification, the front surface may be a surface of a semiconductor chip, which is called an active surface, and on which integrated devices or pads are formed, and the rear surface may be another surface of the semiconductor chip that is opposite to the front surface. A bottom surface of the first semiconductor chip 200 may be the front surface 200a. That is, the first semiconductor chip 200 may be disposed on the package substrate 100 in a face down manner. The first semiconductor chip 200 may include a first base layer 210, a first circuit layer 220, and at least one first penetration via 230.

The first base layer 210 may include a semiconductor material. For example, the first base layer 210 may be a single-crystalline silicon wafer. Semiconductor devices may be disposed in the first base layer 210. In detail, integrated devices or integrated circuits may be formed in a lower portion of the first base layer 210. For example, an integrated device (e.g., a transistor), a passive device (e.g., a resistor, a capacitor, or an inductor), or an interconnection pattern may be formed on a bottom surface of the first base layer 210. That is, the bottom surface of the first base layer 210 may be a front surface, the top surface of the first base layer 210 may be a rear surface.

The first circuit layer 220 may be provided on the bottom surface of the first base layer 210. The first circuit layer 220 may be electrically connected to the integrated device or the integrated circuits, which may be formed in the first base layer 210. For example, the first circuit layer 220 may include a first insulating pattern 222 and a first interconnection pattern 224, which may be disposed in the first insulating pattern 222, and the first interconnection pattern 224 may be coupled to the integrated device or the integrated circuits in the first base layer 210.

The first insulating pattern 222 on the bottom surface of the first base layer 210 may cover the integrated device or the integrated circuits. FIG. 1 illustrates an example in which the first insulating pattern 222 is a single layer, but the inventive concept is not limited to this example. In an embodiment, a plurality of first insulating patterns 222 may be stacked on top of each other. In this case, the first insulating patterns 222 may be interconnection layers, which may be vertically connected to each other. The first insulating pattern 222 may be formed of, or include, silicon oxide (SiO), silicon nitride (SiN), or silicon oxynitride (SiON).

The first interconnection pattern 224 may be disposed in the first insulating pattern 222. In the case where the first insulating pattern 222 is composed of a plurality of layers, the first interconnection pattern 224 may also be composed of a plurality of layers, and one first insulating pattern 222 and one first interconnection pattern 224 therein may constitute a single interconnection layer. The first interconnection pattern 224 may be coupled to the integrated device or the integrated circuits formed in the first base layer 210. That is, the first circuit layer 220 may be electrically connected to the integrated device or the integrated circuits, which may be formed in the first base layer 210. A portion of the first interconnection pattern 224 may be exposed on a bottom surface of the first circuit layer 220. The exposed portion of the first interconnection pattern 224 may serve as a first chip pad 225 of the first semiconductor chip 200. In an embodiment, a plurality of first chip pads 225 may be provided. The first interconnection pattern 224 may include a wiring portion, which is horizontally extended to serve as a horizontal interconnection path, and a via portion, which is vertically extended to serve as a vertical interconnection path. The first interconnection pattern 224 may be formed of, or include, at least one of a metallic material (e.g., copper (Cu) or aluminum (Al)). The bottom surface of the first semiconductor chip 200, on which the first interconnection pattern 224 is provided, may be the active surface of the first semiconductor chip 200.

The first penetration via 230 may vertically penetrate the first base layer 210. For example, the first penetration via 230 may be a pillar-shaped pattern vertically penetrating the first base layer 210. The first penetration via 230 may include an end portion extended toward the front surface 200a of the first semiconductor chip 200 and is connected to the first circuit layer 220. The first penetration via 230 may be coupled to the first interconnection pattern 224 of the first circuit layer 220. The first penetration via 230 may also include an opposite end portion exposed on the top surface of the first base layer 210. For example, the opposite end portion of the first penetration via 230 may be located at the same level as the top surface of the first base layer 210 (i.e., the rear surface 200b of the first semiconductor chip 200). A top surface of the first penetration via 230 and the top surface of the first base layer 210 may be substantially coplanar with each other, thereby forming a substantially flat surface. Alternatively, the first penetration via 230 may protrude above the top surface of the first base layer 210. For example, the opposite end portion of the first penetration via 230 may be located at a level that is higher than the top surface of the first base layer 210. In this case, a protection layer may be provided on the top surface of the first base layer 210 to cover the top surface of the first base layer 210 and enclose the first penetration via 230. A top surface of the first penetration via 230 may be exposed on a top surface of the protection layer. In an embodiment, a plurality of first penetration vias 230 may be provided. The first penetration via 230 may be formed of, or include, at least one metallic material (e.g., copper (Cu) and tungsten (W)).

Although not shown, the first penetration via 230 may further include a via barrier layer enclosing an outer surface of the first penetration via 230. Here, the via barrier layer may not cover a top surface of the first penetration via 230. That is, the top surface of the first penetration via 230 may not be covered with the via barrier layer and may be exposed to the outside of the via barrier layer. The via barrier layer may be used to electrically separate the first penetration via 230 from the first base layer 210. The via barrier layer may be used to prevent a material of the first penetration via 230 from being diffused into the first base layer 210. The via barrier layer may be formed of, or include, at least one conductive metal nitride (e.g., titanium nitride (TiN) and tantalum nitride (TaN)). Alternatively, the via barrier layer may be formed of, or include, an insulating layer. In an embodiment, the via barrier layer may be omitted.

The first semiconductor chip 200 may be mounted on the package substrate 100 in a flip chip manner. For example, the first semiconductor chip 200 may be disposed such that the first chip pads 225 face the package substrate 100. That is, the first semiconductor chip 200 may be disposed such that the front surface 200a of the first semiconductor chip 200 faces the package substrate 100. First chip terminals 240 may be provided between the first chip pads 225 and the package substrate 100. The first chip terminals 240 may be coupled to the first chip pads 225. The first semiconductor chip 200 may be connected to the package substrate 100 through the first chip pads 225, the first chip terminals 240, and the substrate interconnection pattern 120. The first chip terminals 240 may include solder balls or solder bumps.

A first mold layer 410 may be provided on the package substrate 100. The first mold layer 410 may cover a top surface of the package substrate 100. The first mold layer 410 may enclose the first semiconductor chip 200. The first mold layer 410 may protect the first semiconductor chip 200. For example, the first mold layer 410 may cover side surfaces of the first semiconductor chip 200. The first mold layer 410 may fill a space between the package substrate 100 and the first semiconductor chip 200. Between the package substrate 100 and the first semiconductor chip 200, the first mold layer 410 may enclose the first chip terminals 240. The first mold layer 410 may expose a top surface 200b of the first semiconductor chip 200. A top surface of the first mold layer 410 may be coplanar with the top surface 200b of the first semiconductor chip 200, and the top surface of the first mold layer 410 and the top surface 200b of the first semiconductor chip 200 may be substantially flat. The first mold layer 410 may include an insulating material. For example, the first mold layer 410 may be formed of, or include, an epoxy molding compound (EMC).

In an embodiment, an under-fill portion may be disposed between the first semiconductor chip 200 and the package substrate 100. The under-fill portion may include a non-conductive film (NCF). For example, the under-fill portion may be a polymer tape including an insulating material. Alternatively, the under-fill portion may include a fluidic adhesive agent. The under-fill portion may fill a space between the first semiconductor chip 200 and the package substrate 100 and enclose the first chip terminals 240. The under-fill portion may be disposed between the first chip terminals 240, and may prevent an electric short circuit from being formed between the first chip terminals 240. The under-fill portion may protrude laterally in relation to the side surfaces of the first semiconductor chip 200. The first mold layer 410 may surround the first semiconductor chip 200. In an embodiment, the first mold layer 410 on the package substrate 100 may enclose both of the under-fill portion and the first semiconductor chip 200.

A second semiconductor chip 300 may be disposed on the first semiconductor chip 200. The second semiconductor chip 300 may be placed on the rear surface 200b of the first semiconductor chip 200. The first semiconductor chip 200 and the second semiconductor chip 300 may be disposed to form an offset stacking structure. For example, the first semiconductor chip 200 and the second semiconductor chip 300 may be stacked to form a stepwise structure that is upwardly inclined in a first direction D1. In detail, when viewed in a plan view, a portion of the second semiconductor chip 300 may be overlapped with the first semiconductor chip 200, and other portion of the second semiconductor chip 300 may protrude in relation to a side surface of the first semiconductor chip 200 in the first direction D1. That is, the second semiconductor chip 300 may be stacked on the first semiconductor chip 200 to be horizontally offset from the first semiconductor chip 200 in the first direction D1. The second semiconductor chip 300 may be vertically overlapped with the side surface of the first semiconductor chip 200 in the first direction D1. As an example, when viewed from the bottom of the semiconductor package, a portion of a bottom surface of the second semiconductor chip 300 may not be covered with the first semiconductor chip 200 and may be exposed to the outside of the first semiconductor chip 200.

The second semiconductor chip 300 may be provided to have the same or similar structure as the first semiconductor chip 200 described above. For example, the first semiconductor chip 200 and the second semiconductor chip may be of the same kind. As an example, a width of the second semiconductor chip 300 may be substantially equal to a width of the first semiconductor chip 200. Alternatively, the second semiconductor chip 300 may belong to a different kind from the first semiconductor chip 200. The second semiconductor chip 300 may be a logic chip. In an embodiment, the second semiconductor chip 300 may be a memory chip (e.g., DRAM, SRAM, MRAM, or FLASH memory chip). The second semiconductor chip 300 may have a front surface 300a and a rear surface. A bottom surface of the second semiconductor chip 300 may be the front surface 300a. The second semiconductor chip 300 may be disposed on the first semiconductor chip 200 in a face down manner. The second semiconductor chip 300 may include a second base layer 310, a second circuit layer 320, and at least one second penetration via 330.

The second base layer 310 may include a semiconductor material. For example, the second base layer 310 may be a single-crystalline silicon substrate. Semiconductor devices may be provided in the second base layer 310. In detail, an integrated device or integrated circuits may be formed in a lower portion of the second base layer 310. For example, an integrated device (e.g., a transistor), a passive device (e.g., a resistor, a capacitor, or an inductor), or an interconnection pattern may be formed on a bottom surface of the second base layer 310. That is, the bottom surface of the second base layer 310 may be a front surface, and the top surface of the second base layer 310 may be a rear surface.

The second circuit layer 320 may be provided on the bottom surface of the second base layer 310. The second circuit layer 320 may be electrically connected to the integrated device or the integrated circuits formed in the second base layer 310. For example, the second circuit layer 320 may include a second insulating pattern 322 and a second interconnection pattern 324 therein, and here, the second interconnection pattern 324 may be coupled to the integrated device or the integrated circuits formed in the second base layer 310.

On the bottom surface of the second base layer 310, the second insulating pattern 322 may cover the integrated device or the integrated circuits. FIGS. 1 and 3 illustrate an example in which the second insulating pattern 322 is a single layer, but the inventive concept is not limited to this example. In an embodiment, a plurality of second insulating patterns 322 may be provided to be stacked on top of each other. In this case, the second insulating patterns 322 be interconnection layers, which may be vertically connected to each other. The second insulating pattern 322 may be formed of, or include, at least one of silicon oxide (SiO), silicon nitride (SiN), or silicon oxynitride (SiON).

The second interconnection pattern 324 may be disposed in the second insulating pattern 322. In the case where the second insulating pattern 322 is composed of a plurality of layers, the second interconnection pattern 324 may also be composed of a plurality of layers, and on second insulating pattern 322 and one second interconnection pattern 324 therein may constitute a single interconnection layer. The second interconnection pattern 324 may be coupled to the integrated device or the integrated circuits in the second base layer 310. That is, the second circuit layer 320 may be electrically connected to the integrated device or the integrated circuits, which may be formed in the second base layer 310. A portion of the second interconnection pattern 324 may be exposed on a bottom surface of the second circuit layer 320. The exposed portion of the second interconnection pattern 324 may serve as a second chip pad 325 of the second semiconductor chip 300. In an embodiment, a plurality of second chip pads 325 may be provided. The second interconnection pattern 324 may include a wiring portion, which is horizontally extended to serve as a horizontal interconnection path, and a via portion, which is vertically extended to serve as a vertical interconnection path. The second interconnection pattern 324 may be formed of, or include, at least one metallic material (e.g., copper (Cu) and aluminum (Al)). The bottom surface of the second semiconductor chip 300, on which the second interconnection pattern 324 is provided, may be the active surface of the second semiconductor chip 300.

Since the first semiconductor chip 200 and the second semiconductor chip 300 are stacked to form the offset stacking structure, positions of the second chip pads 325 may be different from positions of the first penetration vias 230, when viewed in a plan view. For example, the second chip pads 325 may be offset from the first penetration vias 230 in the vertical direction. More particularly, the second chip pads 325 may not be vertically aligned to the first penetration vias 230. As an example, at least one offset first penetration via 230s of the first penetration vias 230 may be spaced apart from the second semiconductor chip 300 in an opposite direction of the first direction D1. Offset second chip pads 325s of the second chip pads 325 may be spaced apart from the first semiconductor chip 200 in the first direction D1. The second chip pads 325 may be aligned to the first penetration vias 230 in a region where the first semiconductor chip 200 and the second semiconductor chip 300 are vertically overlapped with each other. However, in an embodiment, the second chip pads 325 may not be aligned to the first penetration vias 230 in the overlapping region between the first semiconductor chip 200 and the second semiconductor chip 300.

The second penetration via 330 may vertically penetrate the second base layer 310. For example, the second penetration via 330 may be a pillar-shaped pattern vertically penetrating the second base layer 310. The second penetration via 330 may include an end portion that is extended toward the front surface 300a of the second semiconductor chip 300 and is connected to the second circuit layer 320. The second penetration via 330 may be coupled to the second interconnection pattern 324 of the second circuit layer 320. The second penetration via 330 may also include an opposite end portion that is exposed on the top surface of the second base layer 310. For example, the opposite end portion of the second penetration via 330 may be located at the same level as the top surface of the second base layer 310 (i.e., the rear surface of the second semiconductor chip 300). A top surface of the second penetration via 330 and the top surface of the second base layer 310 may be substantially coplanar with each other, thereby forming a substantially flat surface. Alternatively, the second penetration via 330 may protrude upward in relation to the top surface of the second base layer 310, and a protection layer may be provided on the top surface of the second base layer 310 to cover the top surface of the second base layer 310 and enclose the second penetration via 330. In an embodiment, a plurality of second penetration vias 330 may be provided. The second penetration via 330 may be formed of, or include, at least one metallic material (e.g., copper (Cu) and tungsten (W)). In an embodiment, the second penetration via 330 may further include a via barrier layer disposed to enclose an outer surface of the second penetration via 330.

A redistribution layer 420 may be provided between the first semiconductor chip 200 and the second semiconductor chip 300. The redistribution layer 420 may be in contact with the top surface 200b of the first semiconductor chip 200 and the bottom surface 300a of the second semiconductor chip 300. The redistribution layer 420 may be extended from a region on the first semiconductor chip 200 to a region on the first mold layer 410. For example, the redistribution layer 420 may be provided to cover the top surface 200b of the first semiconductor chip 200 and the top surface of the first mold layer 410. The redistribution layer 420 may be provided for an electric connection between the first and second semiconductor chips 200 and 300. In an embodiment, the redistribution layer 420 may be composed of a single interconnection layer. The interconnection layer may include one redistribution insulating pattern 422 and a redistribution pattern 424 in the redistribution insulating pattern 422.

The redistribution insulating pattern 422 may include at least one of insulating polymers or photoimageable polymers (e.g., photoimageable dielectric (PID)). For example, the redistribution insulating pattern 422 may be formed of, or include, at least one of photo-imagable polyimides, polybenzoxazole (PBO), phenol-based polymers, and benzocyclobutene-based polymers. Alternatively, the redistribution insulating pattern 422 may be formed of, or include, at least one of an insulating material (e.g., silicon oxide (SiO), silicon nitride (SiN), or silicon oxynitride (SiON)).

The redistribution pattern 424 may be disposed in the redistribution insulating pattern 422. In the redistribution insulating pattern 422, the redistribution pattern 424 may be horizontally extended. For example, as shown in FIG. 2, the redistribution pattern 424 may include pad portions 424p and wiring portions 424w. The redistribution pattern 424 may be a structure for horizontal redistribution of signals or power within the redistribution layer 420. The pad portions 424p of the redistribution pattern 424 may be exposed on the top or bottom surface of the redistribution insulating pattern 422, and the wiring portions 424w may connect the pad portions 424p to each other. The wiring portions 424w may extend in a horizontal direction within the redistribution layer 420 to connect the pad portions 424p to each other. The redistribution pattern 424 may include a conductive material. For example, the redistribution pattern 424 may be formed of, or include, at least one metallic material (e.g., copper (Cu)).

The pad portions 424p of the redistribution pattern 424 may be arranged at positions corresponding to the first penetration vias 230 and the second chip pads 325. As an example, the pad portions 424p may be arranged in a first direction D1 and a second direction D2. The first direction D1 and the second direction D2 may be two different directions, which may be parallel to the top surface of the package substrate 100 and may be non-parallel to each other. The first direction D1 and the second direction D2 may be perpendicular to each other. As an example, the pad portions 424p may be arranged in a grid shape. In an embodiment, the pad portions 424p may be arranged in a honeycomb or another shape. The pad portions 424p may be used as substrate pads, to which the first semiconductor chip 200 or the second semiconductor chip 300 may be coupled. For example, some of the pad portions 424p may be disposed on the first semiconductor chip 200. In detail, such pad portions 424p may be disposed on the first penetration vias 230, respectively. At an interface between the redistribution layer 420 and the first semiconductor chip 200, the first penetration vias 230 may be coupled to the pad portions 424p. Some of the pad portions 424p may be disposed below the second semiconductor chip 300. In detail, the pad portions 424p disposed below the second semiconductor chip 300 may be disposed under the second chip pads 325, respectively. At an interface between the redistribution layer 420 and the second semiconductor chip 300, the second chip pads 325 may be coupled to the pad portions 424p.

Since the first semiconductor chip 200 and the second semiconductor chip 300 may be stacked to form the offset stacking structure, the pad portions 424p, which are not vertically overlapped with the first semiconductor chip 200 (i.e., in a region beside the first semiconductor chip 200), may be coupled to the offset second chip pads 325s of the second semiconductor chip 300. Further, the pad portions 424p, which are not vertically overlapped with the second semiconductor chip 300, may be coupled to the offset first penetration vias 230s of the first semiconductor chip 200. In a region where the first semiconductor chip 200 and the second semiconductor chip 300 are vertically overlapped with each other, the pad portions 424p may be aligned to the first penetration vias 230 and the second chip pads 325, as shown in FIG. 2. In this case, one of the first penetration vias 230 and one of the second chip pads 325 may be commonly coupled to one of the pad portions 424p. In an embodiment, in the region where the first semiconductor chip 200 and the second semiconductor chip 300 are vertically overlapped with each other, the pad portion 424p may be aligned to one of the first penetration via 230 or the second chip pad 325. In this case, either the first penetration via 230 or the second chip pad 325 may be coupled to one of the pad portions 424p. The first penetration vias 230 and the second chip pads 325 may be connected to each other by the pad portions 424p of the redistribution layer 420 or through the pad portions 424p and the wiring portions 424w. As an example, each of the wiring portions 424w may connect a pad portion coupled with the first penetration via 230, to a pad portion coupled with the second chip pad 325.

A thickness of the redistribution layer 420 may be less than a thickness of a single interconnection layer in the second circuit layer 320. In detail, a first thickness TH1 of the redistribution pattern 424 of the redistribution layer 420 may be less than a second thickness TH2 of the second interconnection pattern 324. Here, the thickness of the interconnection pattern may mean a thickness of a wiring portion, where the wiring portion may be a horizontally extending portion of the interconnection pattern.

According to an embodiment of the inventive concept, since the first semiconductor chip 200 and the second semiconductor chip 300 are stacked to form the offset stacking structure, at least one of the second chip pads 325 of the second semiconductor chip 300 may not be aligned to the first penetration vias 230 of the first semiconductor chip 200. In particular, depending on the position of the second semiconductor chip 300, some of the second chip pads 325 may be placed in a region that is not overlapped with the first semiconductor chip 200 when viewed in a plan view. However, due to the redistribution layer 420 disposed between the first semiconductor chip 200 and the second semiconductor chip 300, it may be possible to electrically connect the first penetration vias 230 and the second chip pads 325 which may not be aligned to each other. That is, it may be possible to improve the electric connection characteristics between the first semiconductor chip 200 and the second semiconductor chip 300 and realize a semiconductor package with improved electrical characteristics.

In addition, the second semiconductor chip 300 may be electrically connected to the package substrate 100 through the redistribution layer 420 and the first penetration vias 230 of the first semiconductor chip 200. That is, when at least one offset second chip pad 325s of the second chip pads 325 of the second semiconductor chip 300 is disposed in a region that is not overlapped with the first semiconductor chip 200, such offset second chip pads 325s may be electrically connected to the package substrate 100 without a vertical connection structure, such as a conductive post or a bridge chip. Thus, technical constraints (e.g., on the thickness and width of the conductive post), which may be required when the conductive post is formed in the first mold layer 410 during the manufacturing process of the semiconductor package, may be relaxed or eliminated. Furthermore, since the second semiconductor chip 300 may be connected to the package substrate 100 through the first penetration vias 230 in the first base layer 210 of the first semiconductor chip 200, it may be possible to increase an integration density of an interconnection structure connecting the second semiconductor chip 300 to the package substrate 100. As a result, the semiconductor package may be provided with a high integration density. For example, a pitch PI between the first penetration vias 230 and a pitch between the second penetration vias 330 may range from about 4 micrometers (μm) to 30 μm. A third thickness TH3 of the first semiconductor chip 200 and a thickness of the second semiconductor chip 300 may range from about 100 μm to 1000 μm.

A second mold layer 430 may be provided on the redistribution layer 420. The second mold layer 430 may cover the redistribution layer 420. The first mold layer 410 and the second mold layer 430 may be spaced apart from each other by the redistribution layer 420. The second mold layer 430 on the redistribution layer 420 may surround the second semiconductor chip 300. The second mold layer 430 on the redistribution layer 420 may be provided to encapsulate the second semiconductor chip 300. For example, the second mold layer 430 may cover the side and top surfaces of the second semiconductor chip 300. In an embodiment, the second mold layer 430 may expose the top surface of the second semiconductor chip 300. A bottom surface of the second mold layer 430 may be coplanar with the bottom surface 300a of the second semiconductor chip 300. In an embodiment, the redistribution layer 420 may cover the bottom surface of the second mold layer 430 and the bottom surface 300a of the second semiconductor chip 300.

Hereinafter, an element previously described with reference to FIGS. 1 to 5 may be identified by the same reference number without repeating the description thereof. That is, technical features, which are different from those in the embodiments of FIGS. 1 to 3, will be mainly described below.

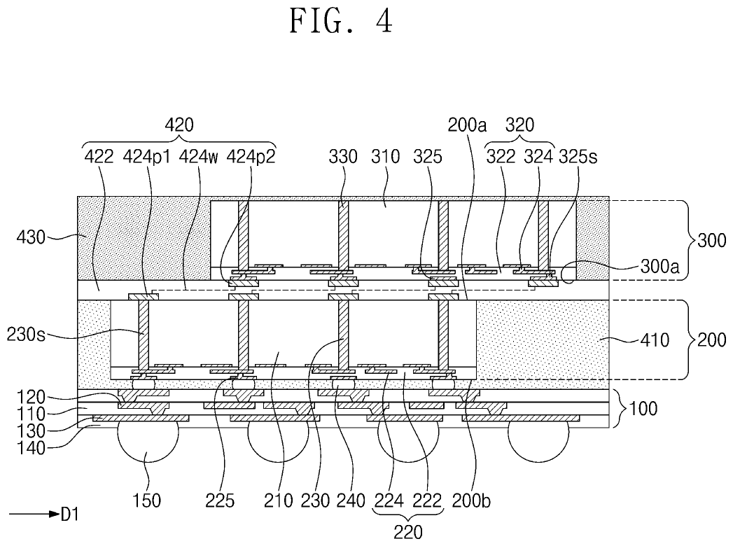

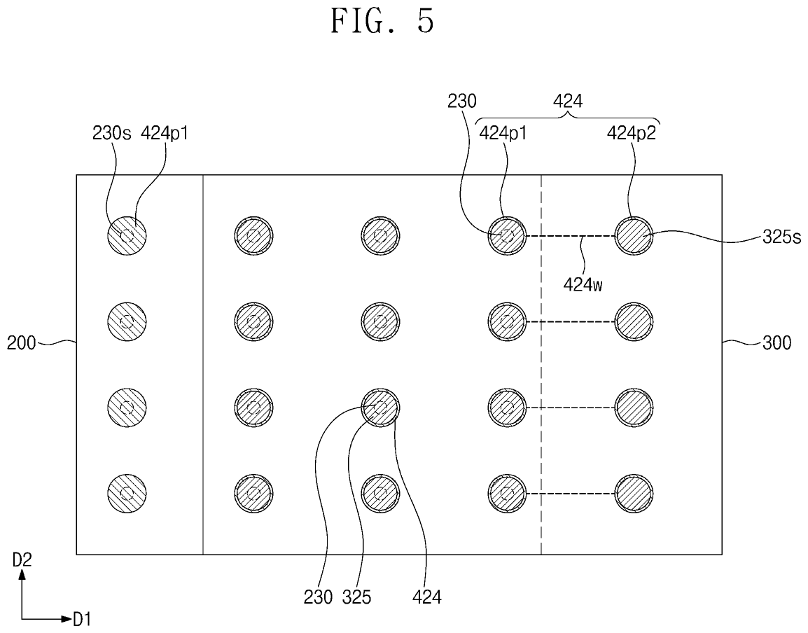

FIG. 4 is a sectional view illustrating a semiconductor package according to an embodiment of the inventive concept. FIG. 5 is a plan view illustrating a semiconductor package according to an embodiment of the inventive concept.

Referring to FIG. 4 and FIG. 5, the redistribution layer 420 may be provided between the first semiconductor chip 200 and the second semiconductor chip 300. The redistribution layer 420 may be in contact with the top surface 200b of the first semiconductor chip 200 and the bottom surface 300a of the second semiconductor chip 300. The redistribution layer 420 may include a plurality of interconnection layers, which may be sequentially stacked. Each of the interconnection layers may include a redistribution insulating pattern 422 and a redistribution pattern 424 disposed therein. The redistribution patterns 424 disposed in adjacent ones of the interconnection layers may be electrically connected to each other.

FIG. 4 illustrates an example in which the redistribution insulating pattern 422 is a single layer, but in an embodiment, the redistribution layer 420 may include a plurality of redistribution insulating patterns 422, which may be vertically stacked. The redistribution patterns 424 may be disposed in each of the redistribution insulating patterns 422.

The redistribution pattern 424 may include first pad portions 424p1 exposed on a bottom surface of the redistribution layer 420 and second pad portions 424p2 exposed on a top surface of the redistribution layer 420. The redistribution pattern 424 may include the wiring portions 424w disposed in the redistribution layer 420. The wiring portions 424w may connect the first pad portions 424p1 to the second pad portions 424p2. The wiring portions 424w may connect one or more of the first pad portions 424p1 offset from the second pad portions 424p2, in a sequential fashion. For example, the wiring portions 424w may connect a left most first pad portion of the first pad portions 424p1 on the first semiconductor chip 200 to a leftmost second pad portion of the second pad portions 424p2 on the second semiconductor chip 300.

Although the wiring portions 424w are depicted with dotted lines in FIG. 4 and FIG. 5, the dotted lines schematically illustrate electrical connection pathways of the wiring portions 424w, and the inventive concept is not limited to the illustrated shapes and positions of the wiring portions 424w.

The first pad portions 424p1 may be placed on the first semiconductor chip 200. The first pad portions 424p1 may be coupled to the first penetration vias 230 at an interface between the redistribution layer 420 and the first semiconductor chip 200.

The second pad portions 424p2 may be disposed below the second semiconductor chip 300. The second pad portions 424p2 may be coupled to the second chip pads 325 at an interface between the redistribution layer 420 and the second semiconductor chip 300.

In the case where, like the embodiment of FIG. 4 and FIG. 5, the redistribution layer 420 may include a plurality of interconnection layers, including the wiring portions 424w. The wiring portions 424w may extend in a horizontal direction within the redistribution layer 420 to connect the first pad portions 424p1 and the second pad portions 424p2, and it may be possible to increase a degree of freedom in constructing an interconnection structure between the first semiconductor chip 200 and the second semiconductor chip 300.

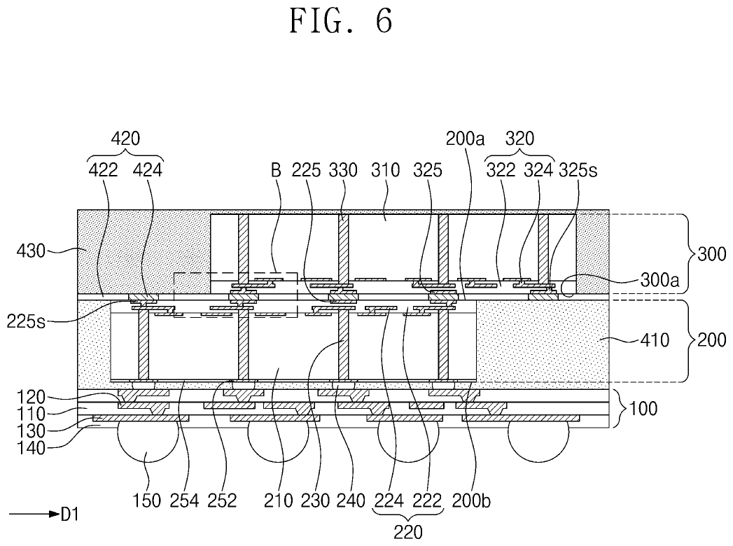

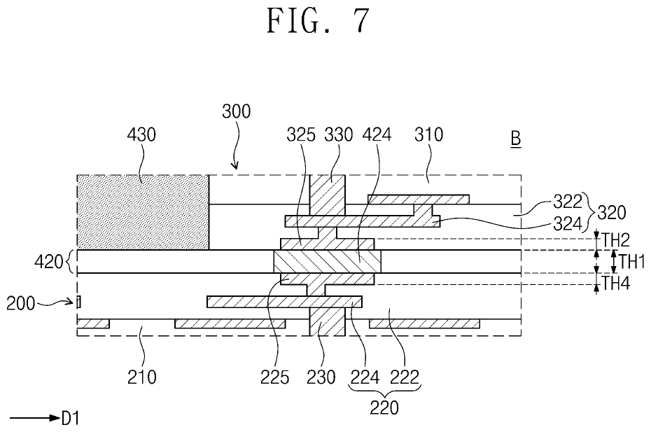

FIG. 6 is a sectional view illustrating a semiconductor package according to an embodiment of the inventive concept. FIG. 7 is an enlarged sectional view illustrating a portion ‘B’ of FIG. 6.

Referring to FIG. 6 and FIG. 7, the first semiconductor chip 200 may be disposed on the package substrate 100. The bottom surface of the first semiconductor chip 200 may be the rear surface 200b. The first semiconductor chip 200 may be disposed on the package substrate 100 in a face-up manner. The first semiconductor chip 200 may include the first base layer 210, the first circuit layer 220, and at least one first penetration via 230.

The first circuit layer 220 may be provided on the top surface of the first base layer 210. The first circuit layer 220 may be electrically connected to the integrated device or the integrated circuits, which may be formed in the first base layer 210. For example, the first circuit layer 220 may include the first insulating pattern 222 and the first interconnection pattern 224 disposed in the first insulating pattern 222. A portion of the first interconnection pattern 224 may be exposed on a top surface of the first circuit layer 220. The exposed portion of the first interconnection pattern 224 may serve as the first chip pad 225 of the first semiconductor chip 200. In an embodiment, a plurality of first chip pads 225 may be provided.

The first penetration via 230 may vertically penetrate the first base layer 210. The first penetration via 230 may include an end portion extended toward the front surface 200a of the first semiconductor chip 200 and connected to the first circuit layer 220. The first penetration via 230 may also include an opposite end portion exposed on the bottom surface of the first base layer 210.

The first semiconductor chip 200 may further include rear pads 252 and a rear protection layer 254.

The rear pads 252 may be disposed on a front surface 200a of the first semiconductor chip 200. Each of the rear pads 252 on the front surface 200a of the first base layer 210 may be connected to a corresponding one of the first penetration vias 230. The rear pads 252 may include a conductive material. For example, the rear pads 252 may be formed of, or include, at least one metallic material (e.g., copper (Cu) and tungsten (W)).

The rear protection layer 254 may be disposed on the bottom surface of the first base layer 210. The rear protection layer 254 may cover the bottom surface of the first base layer 210. The rear protection layer 254 may enclose the rear pads 252. Here, a bottom surface of the rear protection layer 254 and bottom surfaces of the rear pads 252 may be substantially coplanar with each other, thereby forming a substantially flat surface. The rear protection layer 254 may include an insulating material. For example, the rear protection layer 254 may be formed of, or include, at least one of silicon oxide (SiO), silicon nitride (SiN), or silicon oxynitride (SiON). Alternatively, the rear protection layer 254 may include an adhesive material.

The first semiconductor chip 200 may be mounted on the package substrate 100 in a flip chip manner. For example, the first semiconductor chip 200 may be disposed such that the rear pads 252 face the package substrate 100. That is, the first semiconductor chip 200 may be disposed such that the rear surface 200b of the first semiconductor chip 200 faces the package substrate 100. The first chip terminals 240 may be provided between the rear pads 252 and the package substrate 100. The first chip terminals 240 may be coupled to the rear pads 252. The first chip terminals 240 may be electrically connected to the rear pads 252. The first semiconductor chip 200 may be connected to the package substrate 100 through the rear pads 252, the first chip terminals 240, and the substrate interconnection pattern 120.

The second semiconductor chip 300 may be disposed on the first semiconductor chip 200. Since the first semiconductor chip 200 and the second semiconductor chip 300 may be stacked to form the offset stacking structure, positions of the second chip pads 325 may be different from positions of the first chip pads 225. In detail, the second chip pads 325 may not be vertically aligned to the first chip pads 225. For example, at least one offset first chip pad 225s of the first chip pads 225 may be spaced apart from the second semiconductor chip 300 in an opposite direction of the first direction D1. Offset second chip pad 325s of the second chip pads 325 may be spaced apart from the first semiconductor chip 200 in the first direction D1. In a region where the first semiconductor chip 200 and the second semiconductor chip 300 are vertically overlapped with each other, the second chip pads 325 may be aligned to the first chip pads 225. Alternatively, in the region where the first semiconductor chip 200 and the second semiconductor chip 300 are vertically overlapped with each other, the second chip pads 325 may not be vertically aligned to the first chip pads 225.

The redistribution layer 420 may be provided between the first semiconductor chip 200 and the second semiconductor chip 300. The redistribution layer 420 may be in contact with the front surface 200a of the first semiconductor chip 200 and the bottom surface 300a of the second semiconductor chip 300.

The redistribution pattern 424 may be disposed in the redistribution insulating pattern 422. In the redistribution insulating pattern 422, the redistribution pattern 424 may be horizontally extended. Pad portions of the redistribution pattern 424 may be arranged at positions corresponding to the first chip pads 225 and the second chip pads 325. Thus, the redistribution layer 420 may electrically connect the first chip pads 225 and the second chip pads 325 to each other.

A thickness of the redistribution layer 420 may be less than a thickness of each interconnection layer in the first circuit layer 220 and a thickness of each interconnection layer in the second circuit layer 320. In detail, the first thickness TH1 of the redistribution pattern 424 of the redistribution layer 420 may be less than a fourth thickness TH4 of the first interconnection pattern 224 and the second thickness TH2 of the second interconnection pattern 324.

According to an embodiment of the inventive concept, the front surface 200a of the first semiconductor chip 200 and the front surface 300a of the second semiconductor chip 300 may be directly connected to each other through the redistribution layer 420. Thus, a length of an electric connection path between the first semiconductor chip 200 and the second semiconductor chip 300 may be shortened, and thus, a semiconductor package may have improved electrical characteristics.

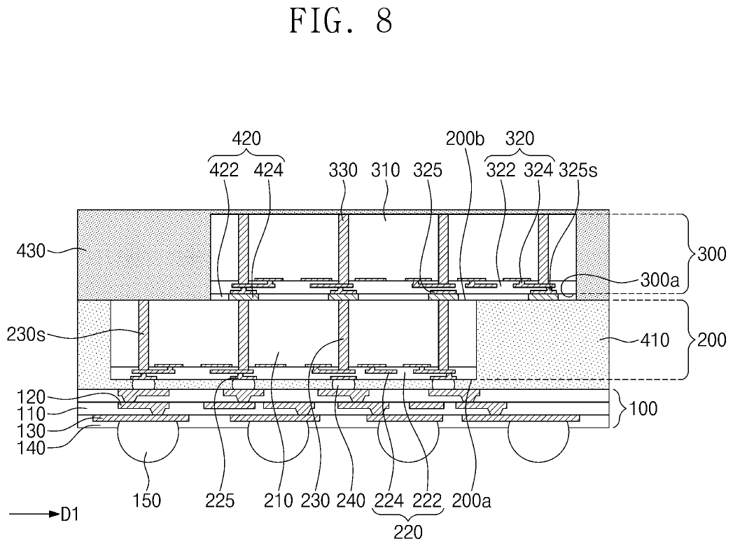

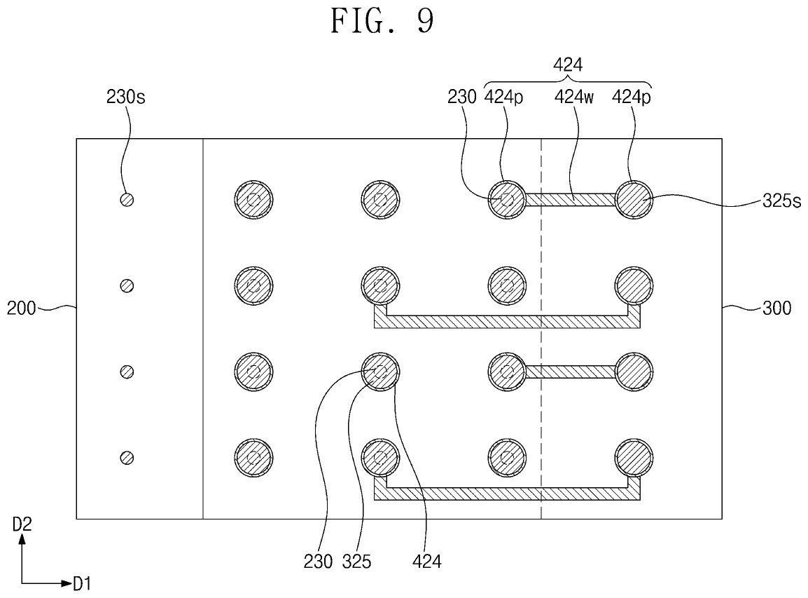

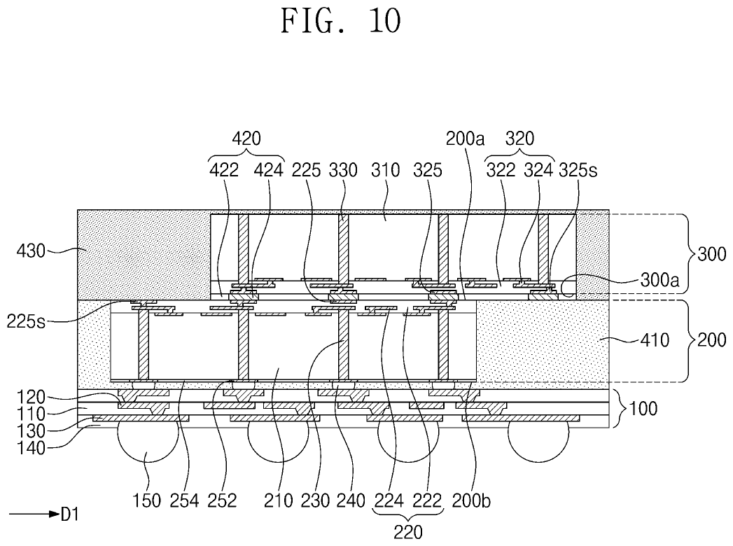

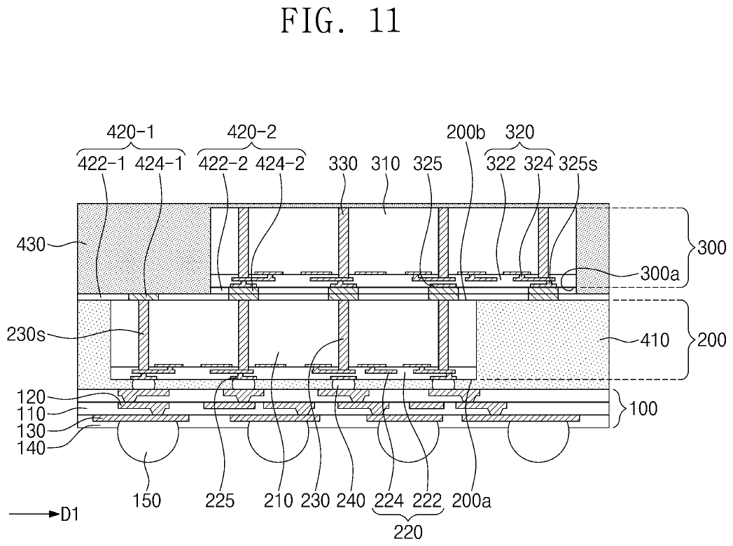

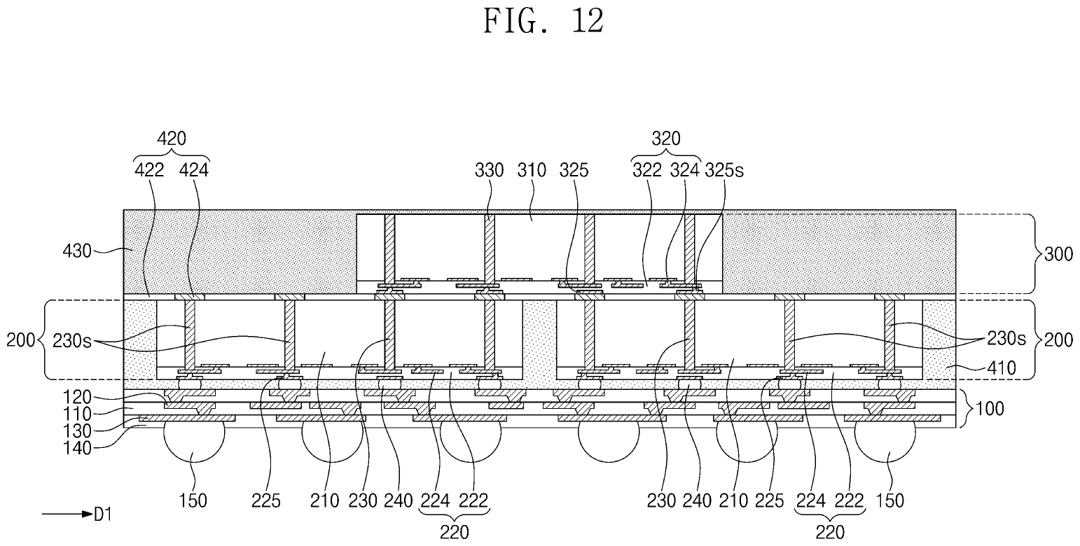

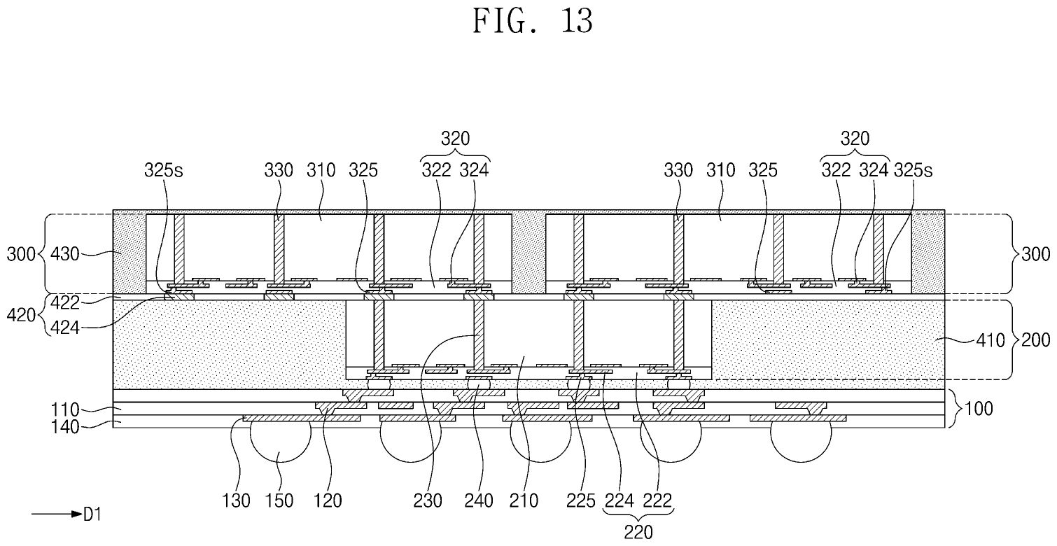

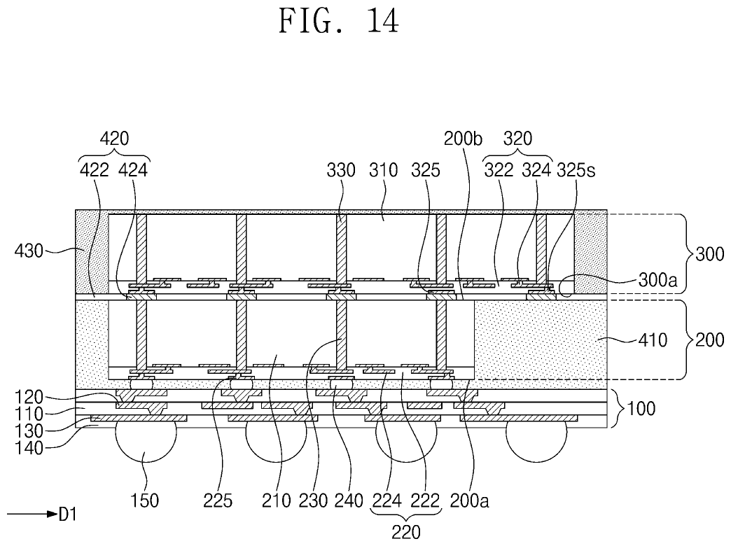

FIG. 8 is a sectional view illustrating a semiconductor package according to an embodiment of the inventive concept. FIG. 9 is a plan view illustrating a semiconductor package according to an embodiment of the inventive concept. FIG. 10 is a sectional view illustrating a semiconductor package according to an embodiment of the inventive concept.

Referring to FIG. 8 and FIG. 9, the redistribution layer 420 may be provided between the first semiconductor chip 200 and the second semiconductor chip 300. The redistribution layer 420 may be in contact with the top surface 200b of the first semiconductor chip 200 and the bottom surface 300a of the second semiconductor chip 300. Here, the redistribution layer 420 may cover the bottom surface 300a of the second semiconductor chip 300 and a portion of the top surface 200b of the first semiconductor chip 200. The redistribution layer 420 may cover the entire bottom surface 300a of the second semiconductor chip 300 and a portion of the top surface 200b of the first semiconductor chip 200. In detail, the redistribution layer 420 may expose a portion of the top surface 200b of the first semiconductor chip 200 that is not vertically overlapped with the second semiconductor chip 300 (i.e., in a region beside the second semiconductor chip 300). The second mold layer 430 may enclose the second semiconductor chip 300 and the redistribution layer 420. In the offset region not vertically overlapped with the second semiconductor chip 300, the second mold layer 430 may be in contact with the exposed portion of the top surface 200b of the first semiconductor chip 200. The first semiconductor chip 200 may expose a portion of the bottom surface of the redistribution layer 420 which is not overlapped with the first semiconductor chip 200. The first mold layer 410 may be in contact with the exposed portion of the bottom surface of the redistribution layer 420 in the offset region not vertically overlapped with the first semiconductor chip 200. The second mold layer 430 may be in contact with the first mold layer 410 in an offset region not vertically overlapped with the first semiconductor chip 200 and the second semiconductor chip 300. The redistribution layer 420 may be provided for an electric connection between the first semiconductor chip 200 and the second semiconductor chip 300. In an embodiment, the redistribution layer 420 may be composed of a single interconnection layer. The interconnection layer may include a redistribution insulating pattern 422 and the redistribution pattern 424 in the redistribution insulating pattern 422.

Since the first semiconductor chip 200 and the second semiconductor chip 300 may be stacked to form the offset stacking structure, the pad portions 424p, which may not be vertically overlapped with the first semiconductor chip 200, may be coupled to the second chip pads 325s of the second semiconductor chip 300. The first penetration vias 230 of the first semiconductor chip 200, which are not vertically overlapped with the second semiconductor chip 300, may not be in contact with the redistribution layer 420. In a region where the first semiconductor chip 200 and the second semiconductor chip 300 are vertically overlapped with each other, one of the pad portions 424p may be commonly coupled to one of the first penetration vias 230 and one of the second chip pads 325, as shown in FIG. 9. However, in an embodiment, one of the pad portions 424p may be coupled to either the first penetration via 230 or the second chip pad 325. The first penetration vias 230 and the second chip pads 325 may be connected to each other by the pad portions 424p of the redistribution layer 420 or through the pad portions 424p and the wiring portions 424w. More particularly, aligned ones of the first penetration vias 230 and the second chip pads 325 may be connected to each other by the pad portions 424p of the redistribution layer 420. Offset ones of the first penetration vias 230 and the second chip pads 325 may be connected to each other through the pad portions 424p and the wiring portions 424w.

Referring to FIG. 9, one or more of the wiring portions 424w may connect pad portions 424p adjacent in the first direction D1. One or more of the wiring portions 424w may connect pad portions 424p remote in the first direction D1, for example, separated by one or more intervening pad portions 424p.

FIG. 8 and FIG. 9 illustrate an example in which the first semiconductor chip 200 is disposed in a face down manner, but the inventive concept is not limited to this example.

Referring to FIG. 10, the first semiconductor chip 200 may be disposed on the package substrate 100 in the same or similar manner as described with reference to FIG. 6. The bottom surface of the first semiconductor chip 200 may be the rear surface 200b. In an embodiment, the first semiconductor chip 200 may be disposed on the package substrate 100 in a face up manner. The first semiconductor chip 200 may include the first base layer 210, the first circuit layer 220, and at least one first penetration via 230. The first semiconductor chip 200 may further include the rear pads 252 and the rear protection layer 254.

Since the first semiconductor chip 200 and the second semiconductor chip 300 may be stacked to form the offset stacking structure, the pad portions of the redistribution pattern 424, which are not vertically overlapped with the first semiconductor chip 200 may be coupled to the second chip pads 325s of the second semiconductor chip 300. The offset first chip pads 225s of the first semiconductor chip 200, which are not vertically overlapped with the second semiconductor chip 300, may not be in contact with the redistribution layer 420. In a region where the first semiconductor chip 200 and the second semiconductor chip 300 are vertically overlapped with each other, one of the pad portions of the redistribution pattern 424 may be commonly coupled to one of the first chip pads 225 and one of the second chip pads 325. In an embodiment, one of the pad portions of the redistribution pattern 424 may be coupled to either the first chip pad 225 or the second chip pad 325.

FIG. 11 is a sectional view illustrating a semiconductor package according to an embodiment of the inventive concept.

Referring to FIG. 11, redistribution layers may be provided between the first semiconductor chip 200 and the second semiconductor chip 300. The redistribution layers may include a first redistribution layer 420-1, which may be provided on the top surface 200b of the first semiconductor chip 200, and a second redistribution layer 420-2, which may be provided on the bottom surface 300a of the second semiconductor chip 300.

The first redistribution layer 420-1 may be provided to have the same or similar structure as the redistribution layer 420 described with reference to FIG. 1. For example, the first redistribution layer 420-1 may be in contact with the top surface 200b of the first semiconductor chip 200. The first redistribution layer 420-1 may be extended from a region on the first semiconductor chip 200 to a region on the first mold layer 410. The first redistribution layer 420-1 may cover the top surface 200b of the first semiconductor chip 200 and the top surface of the first mold layer 410. In an embodiment, the first redistribution layer 420-1 may be composed of a single interconnection layer. The interconnection layer may include one first redistribution insulating pattern 422-1 and a first redistribution pattern 424-1 therein. The first redistribution pattern 424-1 may be coupled to the first penetration vias 230 and 230s of the first semiconductor chip 200.

The second redistribution layer 420-2 may be provided to have the same or similar structure as the redistribution layer 420 described with reference to FIG. 8. For example, the second redistribution layer 420-2 may be in contact with the bottom surface 300a of the second semiconductor chip 300. Here, the second redistribution layer 420-2 may cover the bottom surface 300a of the second semiconductor chip 300. The second redistribution layer 420-2 may cover the entire bottom surface 300a of the second semiconductor chip 300. The second mold layer 430 may enclose the second semiconductor chip 300 and the second redistribution layer 420-2. In an embodiment, the second redistribution layer 420-2 may be composed of a single interconnection layer. The interconnection layer may include one second redistribution insulating pattern 422-2 and a second redistribution pattern 424-2 therein. The second redistribution pattern 424-2 may be coupled to the second chip pads 325 of the second semiconductor chip 300.

The second redistribution layer 420-2 may be disposed on the first redistribution layer 420-1. A top surface of the first redistribution layer 420-1 and a top surface of the second redistribution layer 420-2 may be in contact with each other. The second redistribution layer 420-2 may cover a portion of the top surface of the first redistribution layer 420-1. In detail, the second redistribution layer 420-2 may expose a portion of the top surface of the first redistribution layer 420-1, which is not vertically overlapped with the second semiconductor chip 300. The second mold layer 430 may be in contact with the exposed portion of the top surface of the first redistribution layer 420-1 in an offset region not vertically overlapped with the second semiconductor chip 300. The first redistribution pattern 424-1 of the first redistribution layer 420-1 and the second redistribution pattern 424-2 of the second redistribution layer 420-2 may be connected to each other. The first semiconductor chip 200 and the second semiconductor chip 300 may be electrically connected to each other through the first redistribution layer 420-1 and the second redistribution layer 420-2.

FIG. 12 is a sectional view illustrating a semiconductor package according to an embodiment of the inventive concept.

Referring to FIG. 12, a plurality of first semiconductor chips 200 may be provided. The first semiconductor chips 200 may be spaced apart from each other on the package substrate 100. For example, the first semiconductor chips 200 may be horizontally spaced apart from each other on the package substrate 100.

The second semiconductor chip 300 may be disposed on the first semiconductor chips 200. The second semiconductor chip 300 may be placed on a top surface of the first semiconductor chips 200. For example, the second semiconductor chip 300 may overlap a portion of multiple first semiconductor chips 200. The second semiconductor chip 300 and one of the first semiconductor chips 200 may be disposed to form an offset stacking structure. For example, when viewed in a plan view, a portion of the second semiconductor chip 300 may be overlapped with a first chip of the first semiconductor chips 200, and another portion of the second semiconductor chip 300 may be overlapped with a second chip of the first semiconductor chips 200.

The redistribution layer 420 may be provided between the first semiconductor chips 200 and the second semiconductor chip 300. The redistribution layer 420 may be in contact with the top surfaces of the first semiconductor chips 200 and the bottom surface of the second semiconductor chip 300. The redistribution layer 420 may cover the top surfaces of the first semiconductor chips 200 and the top surface of the first mold layer 410. The redistribution layer 420 may be disposed for making an electric connection between the first semiconductor chips 200 and the second semiconductor chip 300. The redistribution layer 420 may include the redistribution insulating pattern 422 and the redistribution pattern 424 disposed in the redistribution insulating pattern 422. The redistribution pattern 424 may electrically connect the second chip pad 325 of the second semiconductor chip 300 to the first penetration via 230 of the first semiconductor chips 200.

FIG. 13 is a sectional view illustrating a semiconductor package according to an embodiment of the inventive concept.

Referring to FIG. 13, a plurality of second semiconductor chips 300 may be provided. The second semiconductor chips 300 may be spaced apart from each other on the first semiconductor chip 200. The second semiconductor chips 300 may be horizontally spaced apart from each other on the first semiconductor chip 200.

The second semiconductor chips 300 may be disposed on the first semiconductor chip 200. The second semiconductor chips 300 may be placed on a top surface of the first semiconductor chip 200. For example, the first semiconductor chip 200 may overlap a portion of multiple second semiconductor chips 300. Each of the second semiconductor chips 300 and the first semiconductor chip 200 may be disposed to form an offset stacking structure. For example, when viewed in a plan view, each of the second semiconductor chips 300 may include two portions, one of which is overlapped with the first semiconductor chip 200, and the other of which protrudes laterally in relation to the first semiconductor chip 200.

The redistribution layer 420 may be provided between the first semiconductor chip 200 and the second semiconductor chips 300. The redistribution layer 420 may be in contact with the top surface of the first semiconductor chip 200 and the bottom surface of the second semiconductor chips 300. The redistribution layer 420 may cover the top surface of the first semiconductor chip 200 and the top surface of the first mold layer 410. The redistribution layer 420 may be provided for an electric connection between the first semiconductor chip 200 and the second semiconductor chips 300. The redistribution layer 420 may include the redistribution insulating pattern 422 and the redistribution pattern 424 disposed in the redistribution insulating pattern 422. The redistribution pattern 424 may electrically connect the second chip pads 325 of the second semiconductor chips 300 to the first penetration vias 230 of the first semiconductor chip 200.

FIG. 14 is a sectional view illustrating a semiconductor package according to an embodiment of the inventive concept.

Referring to FIG. 14, the second semiconductor chip 300 may have a structure different from the first semiconductor chip 200. For example, a width of the second semiconductor chip 300 may be larger than a width of the first semiconductor chip 200. Thus, the second semiconductor chip 300 may include a protruding portion extended from the first semiconductor chip 200 in the first direction D1 and is not vertically overlapped with the first semiconductor chip 200. As an example, one or more offset second chip pads 325s of the second chip pads 325 of the second semiconductor chip 300 may be disposed in a region beside the first semiconductor chip 200, when viewed in a plan view.

The redistribution layer 420 may be provided between the first semiconductor chip 200 and the second semiconductor chip 300. The redistribution layer 420 may be in contact with the top surface of the first semiconductor chip 200 and the bottom surface of the second semiconductor chip 300. The redistribution layer 420 may cover the top surface of the first semiconductor chip 200 and the top surface of the first mold layer 410. The redistribution layer 420 may be provided for an electric connection between the first semiconductor chip 200 and the second semiconductor chip 300. The redistribution layer 420 may include the redistribution insulating pattern 422 and the redistribution pattern 424 disposed in the redistribution insulating pattern 422. The redistribution pattern 424 may electrically connect the second chip pads 325 of the second semiconductor chip 300 to the first penetration vias 230 of the first semiconductor chip 200.

According to an embodiment of the inventive concept, since the redistribution layer 420 may be provided between the first semiconductor chip 200 and the second semiconductor chip 300, it may be possible to easily form an electric connection structure between the first semiconductor chip 200 and the second semiconductor chip 300, even when the first semiconductor chip 200 and the second semiconductor chip 300 have different sizes from each other.

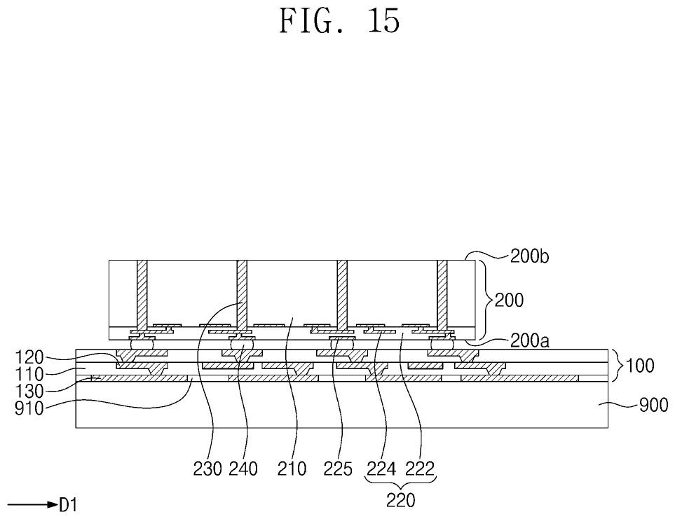

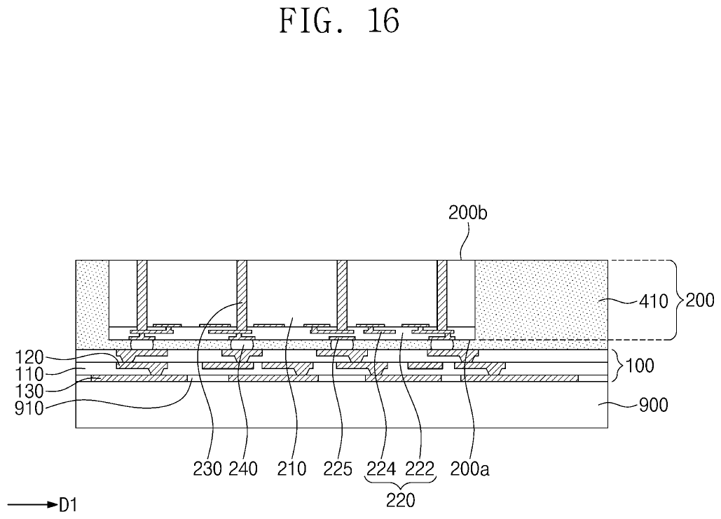

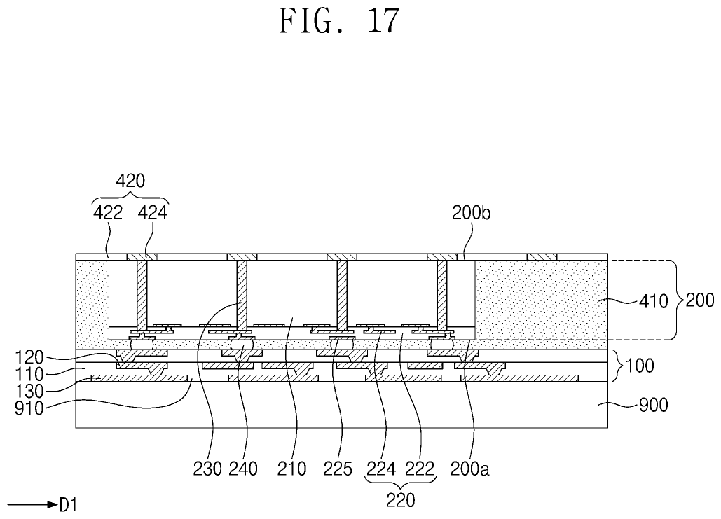

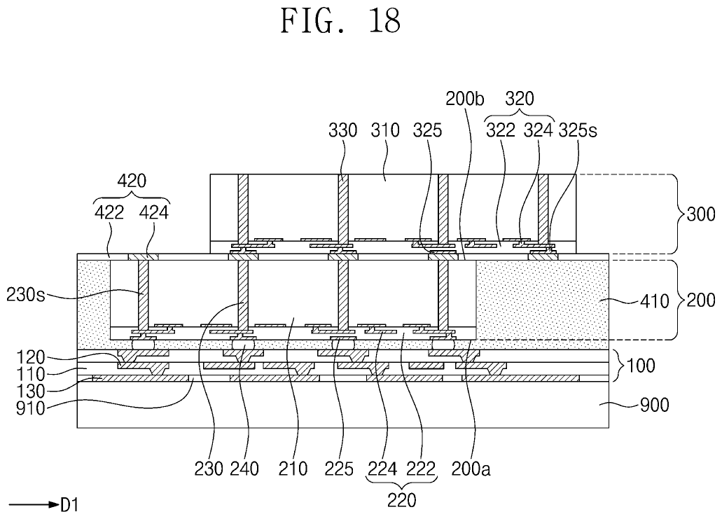

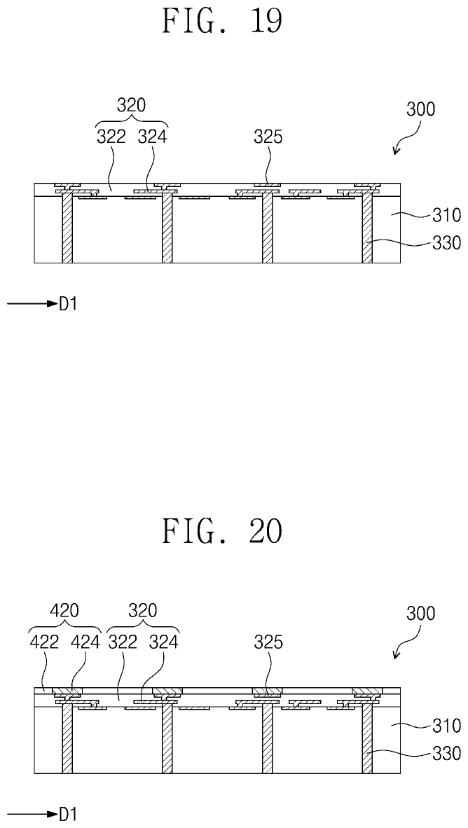

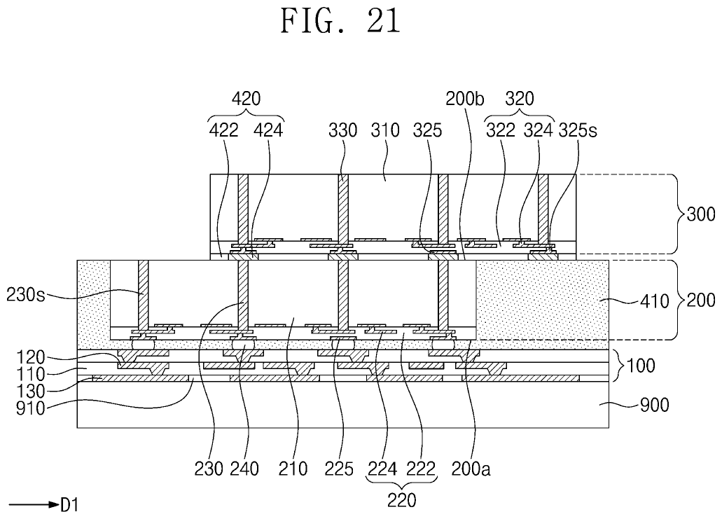

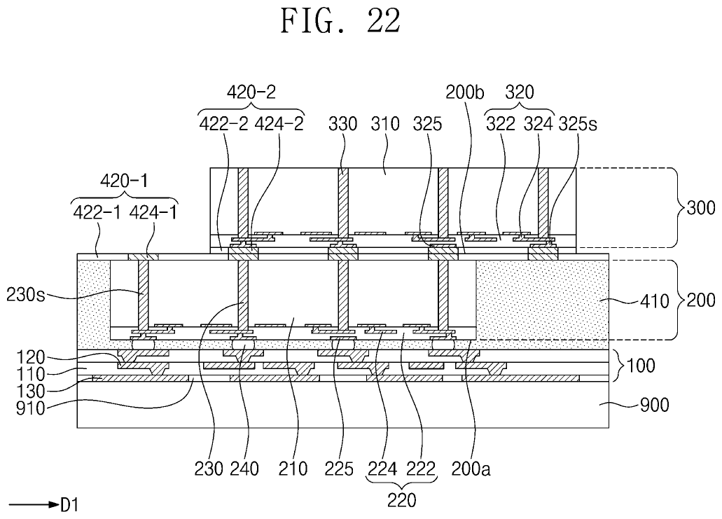

FIG. 15, FIG. 16, FIG. 17, and FIG. 18 are sectional views illustrating a method of manufacturing a semiconductor package according to an embodiment of the inventive concept.

Referring to FIG. 15, a carrier substrate 900 may be provided. The carrier substrate 900 may be an insulating substrate, which may be formed of, or includes, glass or polymer, or a conductive substrate, which may be formed of, or includes, a metallic material. An adhesive member may be provided on a top surface of the carrier substrate 900. In an embodiment, the adhesive member may include an adhesive tape.

The package substrate 100 may be formed on the carrier substrate 900. Hereinafter, a process of forming the package substrate 100 will be described in detail.

A lower insulating layer 910 may be provided on the carrier substrate 900. The lower insulating layer 910 may be formed of, or include, at least one of an insulating polymer or a photoimageable polymer.

The outer pads 130 may be formed in the lower insulating layer 910. For example, the lower insulating layer 910 may be patterned to form openings, in which the outer pads 130 may be disposed, a seed layer may be conformally formed in the openings, and a plating process using the seed layer may be performed to form the outer pads 130 filling the openings.

The substrate insulating layer 110 may be formed on the lower insulating layer 910. The substrate insulating layer 110 may be formed by a coating process (e.g., a spin coating process or a slit coating process).

The substrate interconnection pattern 120 may be formed. For example, the substrate insulating layer 110 may be patterned to form openings exposing the outer pads 130, a barrier layer and a conductive layer may be formed on the substrate insulating layer 110 to fill the openings, and then a planarization process may be performed on the barrier layer and the conductive layer to form the substrate interconnection pattern 120. The substrate insulating layer 110 and the substrate interconnection pattern 120, which may be formed through the above processes, may constitute a substrate interconnection layer. A process of forming the substrate interconnection layer may be repeated to form the package substrate 100, in which a plurality of substrate interconnection layers are stacked. The substrate interconnection pattern 120 in the uppermost one of the substrate interconnection layers may correspond to a substrate pad of the package substrate 100.

The first semiconductor chip 200 may be provided. The first semiconductor chip 200 may have the same or similar structure as the first semiconductor chip 200 described with reference to FIG. 1.

The first semiconductor chip 200 may be mounted on the package substrate 100. For example, solder balls may be provided on the first chip pads 225 of the first semiconductor chip 200. The first semiconductor chip 200 may be placed on the package substrate 100 in such a way that the first chip pads 225 are aligned to the substrate interconnection patterns 120 of the package substrate 100. The first semiconductor chip 200 may be lowered downward to make contact between the solder balls and the substrate interconnection pattern 120, and then, a reflow process may be performed on the solder balls to form the first chip terminals 240 connecting the first semiconductor chip 200 to the package substrate 100.

Referring to FIG. 16, the first mold layer 410 may be formed on the package substrate 100. For example, a first molding material may be coated on the top surface of the package substrate 100 to encapsulate the first semiconductor chip 200, and thereafter, the first molding material may be hardened to form the first mold layer 410. The first mold layer 410 may cover the top surface of the package substrate 100, the side surfaces of the first semiconductor chip 200, and the rear surface of the first semiconductor chip 200. The first semiconductor chip 200 may not be exposed to the outside of the first mold layer 410.

A portion of the first mold layer 410 and a portion of the first semiconductor chip 200 may be removed. In detail, a thinning process may be performed on the first semiconductor chip 200. For example, a grinding or chemical mechanical polishing (CMP) process may be performed on the top surface of the first mold layer 410. Accordingly, the rear surface of the first semiconductor chip 200 and the top surface of the first mold layer 410 may have a flat shape. As a result of the thinning process, an upper portion of the first mold layer 410 may be removed. That is, the rear surfaces of the first semiconductor chips 200 may be exposed to the outside by the thinning process. The rear surface of the first semiconductor chip 200 and the top surface of the first mold layer 410 may be substantially coplanar with each other, thereby forming a flat surface.

Referring to FIG. 17, the redistribution layer 420 may be formed on the first mold layer 410 and the first semiconductor chip 200. For example, the redistribution insulating pattern 422 may be formed by coating or depositing an insulating material on the top surface of the first mold layer 410 and the rear surface of the first semiconductor chip 200. Thereafter, the redistribution insulating pattern 422 may be patterned to form openings, a seed layer may be conformally formed in the openings, and a plating process using the seed layer may be performed to form the redistribution pattern 424 filling the opening. Some of the openings may be formed to expose the first penetration vias 230 of the first semiconductor chip 200. Such openings may define regions for pad portions of the redistribution pattern 424 to be connected to the first semiconductor chip 200. Others of the openings may be formed in a region beside the first semiconductor chip 200. Openings formed in a region beside the first semiconductor chip 200 may define regions for pad portions of the redistribution pattern 424, which may be electrically connected with the second chip pads 325 of the second semiconductor chip 300. In an embodiment, trenches may be formed in the redistribution insulating pattern 422 during forming the openings in the redistribution insulating pattern 422. The trenches may connect the openings to each other. The trench may define a region for the wiring portion of the redistribution pattern 424.

Referring to FIG. 18, the second semiconductor chip 300 may be provided on the redistribution layer 420. For example, the second chip pads 325 of the second semiconductor chip 300 may be aligned to the redistribution pattern 424 of the redistribution layer 420. The second semiconductor chip 300 may be lowered downward to make contact between the second chip pads 325 and the redistribution pattern 424. The second chip pads 325 may be bonded to the redistribution pattern 424 at an interface between the second semiconductor chip 300 and the redistribution layer 420.

Referring to FIG. 1, the second mold layer 430 may be formed on the redistribution layer 420. For example, a second molding material may be coated on the top surface of the redistribution layer 420 to encapsulate the second semiconductor chip 300, and thereafter, the second molding material may be hardened to form the second mold layer 430. The second mold layer 430 may cover the top surface of the redistribution layer 420, the side surfaces of the second semiconductor chip 300, and the rear surface of the second semiconductor chip 300.

The carrier substrate 900 may be removed. Thus, the bottom surface of the package substrate 100 (e.g., the outer pads 130 of the package substrate 100) may be exposed to the outside.

The lower insulating layer 910 may be removed, and the substrate protection layer 140 may be formed under the package substrate 100. The substrate protection layer 140 under the substrate insulating layer 110 may cover the substrate interconnection pattern 120 and the outer pads 130. Alternatively, an insulating layer may be additionally formed on the lower insulating layer 910 by, for example, a coating or deposition method. The lower insulating layer 910, along with the additional insulating layer, may form the substrate protection layer 140.

FIG. 19, FIG. 20, and FIG. 21 are sectional views illustrating a method of manufacturing a semiconductor package according to an embodiment of the inventive concept.

Referring to FIG. 19, the second semiconductor chip 300 may be provided. The second semiconductor chip 300 may have the same or similar structure as the second semiconductor chip 300 described with reference to FIG. 8.

Referring to FIG. 20, the redistribution layer 420 may be formed on the second semiconductor chip 300. For example, the redistribution insulating pattern 422 may be formed by coating or depositing an insulating material on a top surface of the second circuit layer 320 of the second semiconductor chip 300. Thereafter, the redistribution insulating pattern 422 may be patterned to form openings, a seed layer may be conformally formed in the openings, and a plating process using the seed layer may be performed to form the redistribution pattern 424 filling the opening. Some of the openings may be formed to expose the second chip pads 325 of the second semiconductor chip 300. Openings formed to expose the second chip pads 325 of the second semiconductor chip 300 may define regions for pad portions of the redistribution pattern 424 connected to the second semiconductor chip 300. Others of the openings may be formed in a region beside the second semiconductor chip 300. Openings formed in a region beside the second semiconductor chip 300 may define regions for pad portions of the redistribution pattern 424, which may be electrically connected with the first chip pads 225 of the first semiconductor chip 200. In an embodiment, trenches may be formed in the redistribution insulating pattern 422 during forming the openings in the redistribution insulating pattern 422. The trenches may connect the openings to each other. The trench may define a region for the wiring portion of the redistribution pattern 424.

Referring to FIG. 21, the second semiconductor chip 300 may be provided on the structure of FIG. 16 (e.g., disposed on the first semiconductor chip 200 and the first mold layer 410). The redistribution pattern 424 of the redistribution layer 420 may be aligned to the first penetration vias 230 of the first semiconductor chip 200. Thereafter, the second semiconductor chip 300 may be lowered downward to make contact between the redistribution pattern 424 and the first penetration vias 230. The redistribution pattern 424 may be bonded to the first penetration vias 230 at an interface between the redistribution layer 420 and the first semiconductor chip 200.

Referring to FIG. 8, the second mold layer 430 may be formed on the first mold layer 410. For example, a second molding material may be coated on the top surface of the first mold layer 410 and the front surface 200a of the first semiconductor chip 200 to encapsulate the second semiconductor chip 300, and thereafter, the second molding material may be hardened to form the second mold layer 430. The second mold layer 430 may cover the side surfaces of the redistribution layer 420, the side surfaces of the second semiconductor chip 300, and the rear surface of the second semiconductor chip 300.

The carrier substrate 900 may be removed. Thus, the bottom surface of the package substrate 100 (e.g., the outer pads 130 of the package substrate 100) may be exposed to the outside.

The lower insulating layer 910 may be removed, and the substrate protection layer 140 may be formed under the package substrate 100.

FIG. 22 is a sectional view illustrating a method of manufacturing a semiconductor package according to an embodiment of the inventive concept.

Referring to FIG. 22, the structure of FIG. 20 may be provided on the structure of FIG. 16. Here, the redistribution layer 420, which may be manufactured by a method described with reference to FIG. 16, may be referred to as the first redistribution layer 420-1, and the redistribution layer 420, which may be manufactured by a method described with reference to FIG. 20, may be referred to as the second redistribution layer 420-2.

The second semiconductor chip 300 may be provided on the first redistribution layer 420-1. For example, the second redistribution pattern 424-2 of the second redistribution layer 420-2 may be aligned to the first redistribution pattern 424-1 of the first redistribution layer 420-1. The second semiconductor chip 300 may be lowered downward to make contact between the first redistribution pattern 424-1 and the second redistribution pattern 424-2. The first redistribution pattern 424-1 and the second redistribution pattern 424-2 may be bonded to each other at an interface between the first redistribution layer 420-1 and the second redistribution layer 420-2. The first redistribution insulating pattern 422-1 and the second redistribution insulating pattern 422-2 may be in contact with each other at the interface between the first redistribution layer 420-1 and the second redistribution layer 420-2.

Referring to FIG. 11, the second mold layer 430 may be formed on the first redistribution layer 420-1. For example, a second molding material may be coated on the top surface of the first redistribution layer 420-1 to encapsulate the second semiconductor chip 300, and thereafter, the second molding material may be hardened to form the second mold layer 430. The second mold layer 430 may cover the side surfaces of the second redistribution layer 420-2, the side surfaces of the second semiconductor chip 300, and the rear surface of the second semiconductor chip 300. The second mold layer 430 may surround the side surfaces of the second redistribution layer 420-2, the side surfaces of the second semiconductor chip 300, and the rear surface of the second semiconductor chip 300.

The carrier substrate 900 may be removed. Thus, the bottom surface of the package substrate 100 (e.g., the outer pads 130 of the package substrate 100) may be exposed to the outside.

The lower insulating layer 910 may be removed, and the substrate protection layer 140 may be formed under the package substrate 100.

In a semiconductor package according to an embodiment of the inventive concept, a redistribution layer may be provided between stacked semiconductor chips to electrically connect penetration vias or chip pads to each other, where the penetration vias or chip pads may not be aligned to each other. Accordingly, it may be possible to improve the electric connection characteristics between the semiconductor chips and realize a semiconductor package with improved electrical characteristics.

Furthermore, even when chip pads of an upper semiconductor chip are disposed in a region beside a lower semiconductor chip, it may be possible to connect upper chip pads to a package substrate without a vertical connection structure, such as a conductive post or a bridge chip. Thus, technical constraints (e.g., on the thickness and width of the conductive post), which may be required when the conductive post is formed in a mold layer, in a process of manufacturing the semiconductor package, may be relaxed or eliminated. In addition, it may be possible to increase an integration density of an interconnection structure connecting the semiconductor chips to the package substrate. As a result, it may be possible to realize a highly-integrated semiconductor package.

While example embodiments of the inventive concept have been particularly shown and described, it will be understood by one of ordinary skill in the art that variations in form and detail may be made therein without departing from the spirit and scope of the attached claims.

1-5. (canceled)

6. A semiconductor package, comprising:
a package substrate;
a lower semiconductor chip disposed on the package substrate;
an upper semiconductor chip disposed on the lower semiconductor chip and horizontally offset from a portion of the lower semiconductor chip; and
an interconnection layer disposed between the lower semiconductor chip and the upper semiconductor chip,
wherein the interconnection layer covers a bottom surface of the upper semiconductor chip in a first region offset from the lower semiconductor chip,
the upper semiconductor chip comprises a first circuit layer provided on the bottom surface of the upper semiconductor chip, and
a thickness of an interconnection pattern of the first circuit layer is less than a thickness of an interconnection pattern of the interconnection layer.

7. The semiconductor package of claim 6, further comprising:
a first mold layer provided on the package substrate to surround the lower semiconductor chip; and
a second mold layer provided on the first mold layer to surround the upper semiconductor chip,
wherein the interconnection layer is disposed between the first mold layer and the bottom surface of the upper semiconductor chip.

8. The semiconductor package of claim 7, wherein the interconnection layer is disposed between the first mold layer and the second mold layer.

9. The semiconductor package of claim 8, wherein the lower semiconductor chip and the first mold layer are spaced apart from the upper semiconductor chip and the second mold layer by the interconnection layer.

10. The semiconductor package of claim 7, wherein the first mold layer and the second mold layer are in contact with each other in a second region beside the upper semiconductor chip.

11. The semiconductor package of claim 6, wherein the lower semiconductor chip comprises a second circuit layer provided on a top surface of the lower semiconductor chip,
the interconnection layer is directly connected to the first circuit layer and the second circuit layer, and
a thickness of an interconnection pattern of the second circuit layer is less than the thickness of the interconnection pattern of the interconnection layer.

12. The semiconductor package of claim 6, wherein the lower semiconductor chip comprises:
a second circuit layer disposed on a bottom surface of the lower semiconductor chip; and
a plurality of first vias, which are provided to vertically penetrate the lower semiconductor chip, are connected to the second circuit layer, and are exposed on a top surface of the lower semiconductor chip, and
the interconnection layer is directly connected to the first circuit layer and the first vias.

13. The semiconductor package of claim 6, wherein the interconnection layer comprises:
a first redistribution layer in contact with a top surface of the lower semiconductor chip; and
a second redistribution layer in contact with the bottom surface of the upper semiconductor chip,
wherein the first redistribution layer is overlapped with both the top surface of the lower semiconductor chip and the bottom surface of the upper semiconductor chip, and
the second redistribution layer is overlapped with the bottom surface of the lower semiconductor chip and is offset from at least a portion of the top surface of the lower semiconductor chip.

14. The semiconductor package of claim 6, wherein the lower semiconductor chip comprises a plurality of first vias, which are provided to vertically penetrate the lower semiconductor chip and are connected to a second circuit layer of the lower semiconductor chip,
the upper semiconductor chip comprises a plurality of second vias, which are provided to vertically penetrate the upper semiconductor chip and are connected to the first circuit layer, and a plurality of chip pads disposed in the first circuit layer, and
at least one of the chip pads is offset from the lower semiconductor chip, when viewed in a plan view,
wherein the interconnection pattern of the interconnection layer electrically connects the at least one of the chip pads to the first vias.

15. (canceled)

16. A semiconductor package, comprising:
a package substrate;
a first semiconductor chip disposed on the package substrate;
a first mold layer disposed on the package substrate to surround the first semiconductor chip;
a first interconnection layer covering a top surface of the first semiconductor chip and a top surface of the first mold layer;
a second semiconductor chip on the first interconnection layer;
a second mold layer disposed on the first interconnection layer to surround the second semiconductor chip; and
a plurality of outer terminals disposed on a bottom surface of the package substrate,
wherein the second semiconductor chip is horizontally offset from the first semiconductor chip and vertically overlaps a side surface of the first semiconductor chip, and
the first semiconductor chip and the first mold layer are spaced apart from the second semiconductor chip and the second mold layer by the first interconnection layer.

17. The semiconductor package of claim 16, wherein the first semiconductor chip comprises:
a first circuit layer disposed on a surface of the first semiconductor chip; and
a plurality of first vias disposed to vertically penetrate the first semiconductor chip and coupled to the first circuit layer,
wherein the second semiconductor chip comprises:
a second circuit layer disposed on a surface of the second semiconductor chip; and
a plurality of second vias disposed to vertically penetrate the second semiconductor chip and coupled to the second circuit layer.

18. The semiconductor package of claim 17, wherein the first circuit layer is disposed on the top surface of the first semiconductor chip facing the second semiconductor chip,
the second circuit layer is disposed on a bottom surface of the second semiconductor chip facing the first semiconductor chip, and
the first interconnection layer is coupled to the first circuit layer and the second circuit layer.

19. The semiconductor package of claim 17, wherein the first circuit layer is disposed on a bottom surface of the first semiconductor chip facing the package substrate,
the second circuit layer is disposed on a bottom surface of the second semiconductor chip facing the first semiconductor chip, and
the first interconnection layer is coupled to the first vias exposed on the top surface of the first semiconductor chip, and the second circuit layer.

20. The semiconductor package of claim 17, wherein a thickness of an interconnection pattern of the first circuit layer and a thickness of an interconnection pattern of the second circuit layer are less than a thickness of an interconnection pattern of the first interconnection layer.

21. The semiconductor package of claim 17, further comprising a plurality of chip pads of the second circuit layer, which are connected to the plurality of second vias,
wherein at least one of the chip pads of the second circuit layer is offset from the side surface of the first semiconductor chip, when viewed in a plan view, and
an interconnection pattern of the first interconnection layer electrically connects the at least one of the chip pads of the second vias to the first vias.

22. The semiconductor package of claim 16, further comprising a second interconnection layer provided on a bottom surface of the second semiconductor chip,
wherein the second mold layer on the first interconnection layer encloses the second semiconductor chip and the second interconnection layer.

23. The semiconductor package of claim 22, wherein the second interconnection layer is disposed between the first mold layer and the second semiconductor chip and between the first semiconductor chip and the second semiconductor chip and is exposed a top surface of the first interconnection layer in a region beside the second semiconductor chip.

24. A semiconductor package, comprising:
a package substrate;
a first semiconductor chip disposed on the package substrate, the first semiconductor chip comprising a first circuit layer, which is disposed on a surface of the first semiconductor chip, and a plurality of first vias, which vertically penetrate the first semiconductor chip and are coupled to the first circuit layer;
a first mold layer disposed on the package substrate to enclose the first semiconductor chip;
a second semiconductor chip disposed on and offset from the first semiconductor chip, the second semiconductor chip comprising a second circuit layer, which is disposed on a bottom surface of the second semiconductor chip, and a plurality of second vias vertically penetrating the second semiconductor chip and are coupled to the second circuit layer;
a first interconnection layer disposed between the second circuit layer and the first semiconductor chip and between the second circuit layer and the first mold layer; and
a second mold layer disposed on the first mold layer to enclose the first interconnection layer and the second semiconductor chip,
wherein the first interconnection layer exposes a top surface of the first semiconductor chip in a region beside the second semiconductor chip,
the second semiconductor chip is connected to the first interconnection layer through a plurality of chip pads of the second circuit layer,
at least one of the chip pads is disposed on a side surface of the first semiconductor chip, when viewed in a plan view, and
an interconnection pattern of the first interconnection layer electrically connects the at least one of the chip pads to the first vias.

25. The semiconductor package of claim 24, wherein a thickness of an interconnection pattern of the second circuit layer is less than a thickness of the interconnection pattern of the first interconnection layer.

26. The semiconductor package of claim 24, wherein the first mold layer and the second mold layer are in contact with each other beside the second semiconductor chip.

27-34. (canceled)
